(19) United States
(12) Patent Application Publication
(10) Pub. No.: US 2010/0095880 A1
(43) Pub. Date: Apr. 22, 2010

(54) Arc melting high-purity carbon electrode and application thereof

(75) Inventors: Masanori FUKUI, Akita-shi (JP); Koichi SUZUKI, Akita-shi (JP); Takeshi FUJITA, Akita-shi (JP)

Correspondence Address: GREENBLUM & BERNSTEIN, P.L.C., 1950 ROLAND CLARKE PLACE, RESTON, VA, 20191, US

(73) Assignees: JAPAN SUPER QUARTZ CORPORATION, Akita-shi (JP); SUMCO CORPORATION, Tokyo (JP)

(21) Appl. No.: 12/253,370

(22) Filed: Oct. 17, 2008

(51) Int. Cl. H05B 7/06; C30B 15/10; C30B 15/16; B29C 35/00

(52) U.S. Cl. 117/13; 373/88; 117/217; 425/174.8 R

(57) ABSTRACT

An arc melting high-purity carbon electrode is capable of forming stable arc at the time of arc discharge, and it is possible to produce a vitreous silica crucible with good properties, which does not cause local lack of the electrode and does not create black foreign materials or concave portions on the inner surface of the crucible. The arc melting high-purity carbon electrode is a carbon electrode used to heat and melt silica powder by arc discharge, in which the density of the carbon electrode is equal to or more than 1.60 g/cm³ and equal to or less than 1.80 g/cm³, and is formed of high-purity carbon particles having a diameter of 0.05 mm or less.

### BACKGROUND OF THE INVENTION

1. Field of the Invention

The present invention relates to an arc melting high-purity carbon electrode, in which silica fumes occurring when silica powder is heated and melted by arc discharge is hardly adhered, and thus it is prevented that cohering silica fumes drops into melted vitreous silica to cause poor properties; an apparatus for producing a vitreous silica crucible provided with the arc discharge device; and applications thereof.

2. Related Art

A vitreous silica crucible used to pull up a single crystal silicon is produced mainly by an arc melting method. In this method, silica powder is deposited on the inner surface of a carbon mold at a regular thickness, and the silica deposited layer is heated and melted by arc discharge of a carbon electrode provided above the silica deposited layer into glass, thereby producing a vitreous silica crucible.

In the producing process, at the time of arc melting of silica powder, a part of silica powder heated at high temperature is melted and vaporized to create silica fumes. In this case, there is a problem that this silica fumes is attached to an electrode surface and the cohering silica fumes drops into melted vitreous silica (dropping phenomenon), whereby a foreign material is attached to the inner surface of the glass crucible or the homogeneity of the glass deteriorates.

When homogeneity of the carbon electrode is not appropriate, arc is not uniform to cause loss of the electrode. Then, the missing carbon piece is attached to the surface of the silica crucible, and black foreign materials are generated by incomplete combustion of the carbon piece. Even in the case of complete combustion, concave portions occur on the surface of the crucible to cause a poor shape. Particularly, at the time of reproducing a crucible, to prevent the crucible from being deformed, arc power and arc time are small as compared with the case at the time of producing a crucible. Accordingly, black foreign materials are usually caused by incomplete combustion of the missing carbon piece.

A carbon electrode is gradually consumed by burning carbon particles forming the electrode from the surface thereof by arc discharge. The burned carbon particles having a small diameter are burned out before reaching the surface of the crucible. However, when the diameter of the particles is too large, they are not burned until reaching the inner surface of the crucible. Then, the remaining particles become black foreign materials or are burned on the inner surface of the crucible to cause concave portions. The black foreign materials or the unevenness of the inner surface of the crucible result in a decrease of a single crystal yield at the time of pulling up a single crystal silicon.

To solve the aforementioned problem, there has been known a carbon electrode in which the maximum diameter of carbon particles is 150 μm or less, the electrode density is 1.80 g/cm³ or more, and the 3-point bending strength is 35 MPa or more (Patent Document 1). In addition, there has been known an arc melting high-purity carbon electrode in which a particle diameter is 0.05 to 0.5 mm (Patent Document 2).

Patent Document 1: Japanese Patent Application Laid-Open No. 2001-97775

Patent Document 2: Japanese Patent Application Laid-Open No. 2002-68841

However, since the carbon electrode described in Patent Document 1 is formed using very fine particles having high density and high strength, there is a problem of high production cost. In addition, when the electrode density is not uniform, arc is unstable to easily cause loss of the electrode. When the electrode density is too high, intercoupling of carbon particles is too strong. Accordingly, the cohering carbon particles are scattered by consumption of the electrode at the time of generating arc, and all of the carbon particles are not burned out and drop onto the inner surface of the crucible to cause black foreign materials or concave portions. The high-purity carbon electrode described in Patent Document 2 is very economical, but there is room for improvement about homogeneity of electrode density and diameters of carbon particles.

### SUMMARY OF THE INVENTION

The invention has been made to solve the aforementioned problems in the known arc heating carbon electrodes, and is to provide an arc melting high-purity carbon electrode, which is very economical and does not generate black foreign materials, concave portions, or the like on an inner surface of a crucible in producing and reproducing a vitreous silica crucible; an apparatus for producing a vitreous silica crucible having arc discharge device thereof; a vitreous silica crucible produced or reproduced by the producing apparatus; and a method for pulling up a single crystal silicon using the vitreous silica crucible.

The invention relates to an arc melting high-purity carbon electrode, an apparatus for producing a vitreous silica crucible having arc discharge device thereof, and applications thereof, to solve the aforementioned problems by the following features.
(1) An arc melting high-purity carbon electrode used to heat and melt silica powder by arc discharge, wherein the density of the carbon electrode is 1.60 g/cm³ or more and 1.80 g/cm³ or less, and the carbon electrode is formed of high-purity carbon particles having diameters of 0.05 mm or less.
(2) An apparatus for producing a vitreous silica crucible including arc discharge device having the carbon electrode according to the above (1).
(3) A vitreous silica crucible for pulling-up a single crystal silicon, produced or reproduced using the producing apparatus according to the above (2).

A vitreous silica crucible for pulling up a single crystal silicon can be reproduced by the two following methods.

One method is the following method: a vitreous silica crucible to be recycled is made be toward the outside (side coming into contact with a mold) of a silica powder formed article, silica powder is deposited on the inner surface thereof and is heated and melted, or a non-bubble and non-impurity layer is formed on the inner surface by a thermal spraying method. The thermal spraying method is as follows: while silica powder previously deposited on a rotary mold is heated and melted by arc discharge, silica powder is additionally dropped down to pass through the inside of the arc discharge and is heated and melted, and the melted vitreous silica is deposited on the inner surface of a vitreous silica crucible to form a vitreous silica crucible having a transparent layer.

The other method is a method of re-melting the surface of a crucible. Particularly, the method is used to control a bubble containing state (in case of about 3 mm, bubbles are get out by heating and thus the state becomes a non-bubble state) on the inner surface or a surface state such as surface roughness. In the control of the surface state such as surface roughness, to prevent vibration of a melt surface, it is preferable that a surface be rough at a part (upper part of the inside wall) coming into contact with the melt surface at the time pulling up of the single crystal silicon is started. In addition, it is preferable that a surface be smooth throughout a lower surface at a curbed portion. (4) A method for pulling up a single crystal silicon using the vitreous silica crucible according to the above (3).

The arc melting high-purity carbon electrode of the invention generates stable arc at the time of heating and melting silica powder, and does not cause local lack of the electrode. In addition, since carbon particles burned and scattered at the time of arc is completely burned. Accordingly, there is no case where the carbon particles drop onto the melted glass surface to form black foreign materials or concave portions.

According to the apparatus for producing a vitreous silica crucible provided with the arc discharge device having the high-purity carbon electrode, it is possible to produce a high-quality vitreous silica crucible, and it is possible to obtain a satisfactory single crystal yield in pulling up a single crystal silicon by the vitreous silica crucible.

### BRIEF DESCRIPTION OF THE DRAWINGS

FIG. 1 is a sectional view illustrating an embodiment of an apparatus for producing a vitreous silica member according to the invention.

FIG. 2 is a longitudinal sectional view illustrating an embodiment of a vitreous silica crucible according to the invention.

FIG. 3 is a sectional view illustrating another embodiment of a vitreous silica crucible according to the invention.

FIG. 4 is a longitudinal section view illustrating a state of pulling up a single crystal silicon ingot from a silicon melt in a vitreous silica crucible of an embodiment.

### PREFERRED EMBODIMENT

Hereinafter, the invention will be described in detail with reference to examples.

An arc melting high-purity carbon electrode of the invention is a carbon electrode used to heat and melt silica powder by arc discharge, in which the density of the carbon electrode is equal to or greater than 1.60 g/cm³ and equal to or less than 1.80 g/cm³, and is characterized in that the carbon electrode is formed of high-purity carbon particles having a diameter of 0.05 mm or less.

A carbon electrode is formed by coupling high-purity carbon particles. A carbon electrode according to the invention has a forming density (electrode density) equal to or more than 1.60 g/cm³ and equal to or less than 1.80 g/cm³. When a forming density of an electrode is lower than 1.60 g/cm³, intercoupling of carbon particles is not sufficient. Accordingly, local lack of the electrode easily occurs at the time of generating arc. In addition, when the forming density is lower than 1.60 g/cm³, a smoothing property of the electrode surface is low. Accordingly, silica fumes generated at the time of heating and melting silica powder is easily attached to the electrode surface, and the attached fumes coheres and drops onto the inner surface of the crucible to cause foreign materials.

When the forming density of the electrode is higher than 1.80 g/cm³, the coupling of carbon particles is strong. Thus, when carbon particles burned by consumption of the electrode at the time of generating arc are scattered, cohering carbon particles having a large diameter in appearance are scattered, and all of them are not burned out and drop onto the inner surface of the crucible, thereby causing black foreign materials or concave portions, which is not preferable.

The carbon electrode of the invention has an electrode density equal to or more than 1.60 g/cm³ and equal to or less than 1.80 g/cm³ throughout the whole electrode, in which the difference in density is limited to 0.2 g/cm³, and has a high homogeneity. Accordingly, the generated arc is stable, and thus the carbon electrode does not generate local lack of the electrode. When the difference in density of the electrode is larger than 0.2 g/cm³, arc is unstable and thus local lack of the electrode is easily generated.

The high-purity carbon electrode of the invention is formed of high-purity carbon particles with a diameter of 0.05 mm or less, and preferably 0.02 mm or less. When the diameter of the carbon particles is larger than 0.05 mm, all of the burned and scattered carbon particles are not burned out at the time of consuming the electrode and generating arc, and drop onto the inner surface of the crucible, thereby easily forming black foreign materials. When the diameter of the particles is too much larger than the aforementioned range, the smoothness of the surface of the carbon electrode is reduced. Accordingly, the silica fumes generated at the time of heating and melting silica powder easily attaches to the surface of the electrode, which is not preferable.

To measure a particle diameter, a laser diffraction and diffusion method may be used.

When a particle is illuminated with a laser beam, light emits from the particle in various directions of front, rear, up, down, left, and right directions. This light is called as “diffraction and diffusion light”. Intensity of diffraction and difflusion light draws a regular space pattern in a direction of emitting light. This is “light intensity distribution pattern”. It has been known that the “light intensity distribution pattern” is changed to various types according to the size of the particle. There is a one-to-one corresponding relationship between the size of the particle and the light intensity distribution pattern. That is, it is possible to measure the size of a particle by detecting a light intensity distribution pattern. In actual measurement of distribution in particle sizes, the measurement target is not a single particle but a particle group including a plurality of particles. Since the particle group including a plurality of particles having different sizes, a light intensity distribution pattern of the emitted light becomes superposition of diffraction and diffusion light from the particles. Accordingly, it is possible to obtain sizes and a ratio (distribution in particle sizes) of particles included in the group by analyzing the light intensity distribution pattern.

The diameters of the carbon particles of the invention can be confirmed by observing composition of the carbon electrode using a polarizing microscope.

In Patent Document 2, the optimal diameter of carbon particles is set in the range of 0.05 mm to 0.5 mm. In carbon particles having a diameter smaller than 0.05 mm, there is no dropping phenomenon and the properties of a crucible are satisfactory but consumption of the electrode is considerable. However, it is possible to obtain a high-quality carbon electrode with little consumption of the electrode by controlling an electrode density in the aforementioned range (equal to or more than 1.60 g/cm³ and equal to or less than 1.80 g/cm³).

In producing a vitreous silica crucible used to pull up a single crystal silicon, a high-purity carbon electrode is used to prevent metal pollution of the crucible. In the carbon electrode of the invention, the same high-purity carbon particles as the known high-purity carbon particles are used.

The high-purity carbon electrode of the invention may be produced, for example, by a cold isotropic press method (CIP method). According to this forming method, it is possible to obtain a carbon electrode having excellent homogeneity and high density using carbon powder. A binder combined with carbon particles is not particularly limited. In producing such a kind of carbon electrode, the known binder may be used.

The high-purity carbon electrode of the invention is used, for example, as an electrode of arc discharge device of alternating current 3-phase (R phase, S phase, T phase), and is used for an apparatus for producing a vitreous silica crucible having the arc discharge device. The invention includes arc discharge device having the high-purity carbon electrode and an apparatus for producing a vitreous silica crucible having the arc discharge device.

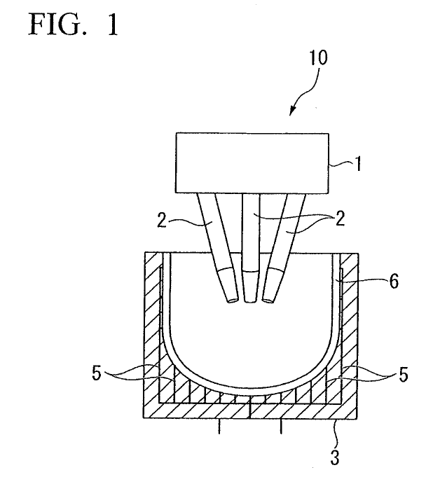

FIG. 1 shows an example of an apparatus for producing a vitreous silica crucible usable in the invention. This apparatus mainly includes a bottomed cylindrical mold 3, a driving mechanism (not shown) for rotating the mold 3 around an axis, and an arc discharge device 10 for heating the inside of the mold 3. The mold 3 is formed, for example, of carbon, and a number of decompression passages 5 open to the inner surface of the mold 3 are formed therein. The decompression passage 5 is connected to a decompression mechanism (not shown), and the mold 3 is configured to suction in air from the inner surface through the decompression passage 5 at the time of rotation. A silica deposited layer 6 can be formed in the inner surface of the mold 3 by depositing silica powder. The silica deposited layer 6 is kept on the inner wall surface by centrifugal force caused by the rotation of the mold 3. The kept silica deposited layer 6 is heated by the arc discharge device 10 while performing decompression through the depression passage 5, thereby melting the silica deposited layer 6 to form a vitreous silica layer. The vitreous silica crucible after cooling is taken out of the mold 3 and is shaped, thereby producing a vitreous silica crucible.

The arc discharge device 10 includes a plurality of carbon electrodes 2 formed of high-purity carbon and having a rod shape, an electrode moving mechanism 1 holding and moving the carbon electrodes 2, and a power supply (not shown) for providing electric current to each carbon electrode 2. In this example, the number of carbon electrodes 2 is 3, but may be 2, 4, or more as long as arc discharge can be performed between the carbon electrodes 2. The shape of the carbon electrode 2 is not limited. The carbon electrodes 2 are disposed to get gradually closer to one another toward the leading ends. The power supply may be an alternating current supply or a direct current power supply. In the embodiment, three carbon electrodes 2 are connected to three phases of three-phase alternating current, respectively.

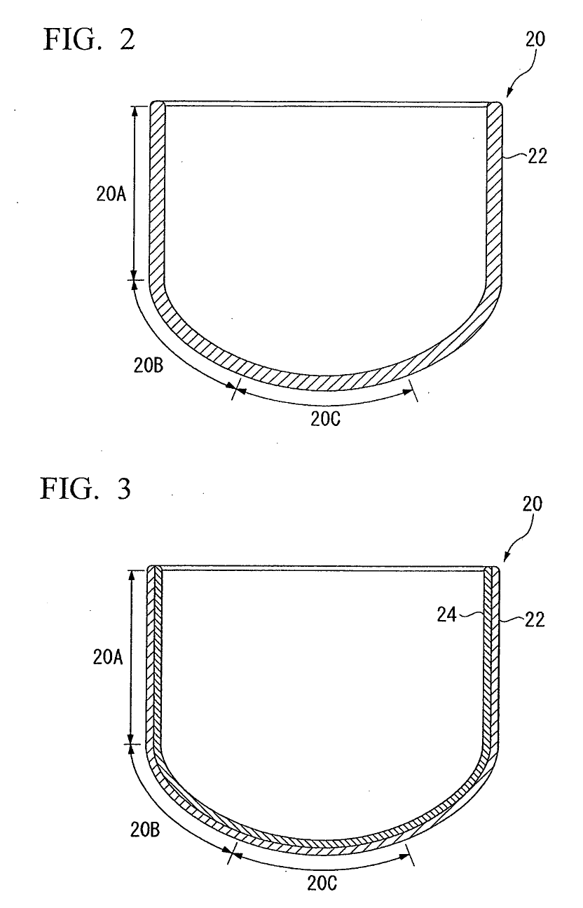

FIG. 2 shows an embodiment of a vitreous silica crucible. This vitreous silica crucible 20 has a wall portion 20A, a curved portion 20B, and a bottom portion 20C, and is formed of vitreous silica 22 which is easily crystalized and containing no crystallization accelerator.

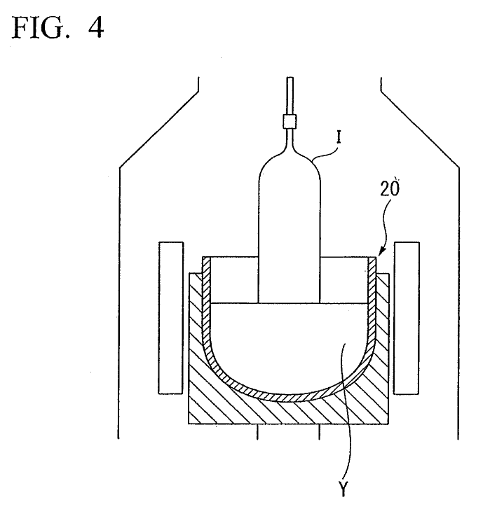

FIG. 3 shows another embodiment of a vitreous silica crucible. This vitreous silica crucible 20 has a wall portion 20A, a curved portion 20B, and a bottom portion 20C. An inner surface layer thereof is formed of synthetic silica glass 24, and an outer surface layer is formed of quartz glass 22 formed from natural quartz into glass which is easily crystalized and containing no crystallization accelerator.

The invention includes a method for producing a single crystal silicon including a process of melting polycrystal silicon in a crucible, and a process of immersing a seed of single crystal silicon in melted silicon to pull up a single crystal silicon ingot.

FIG. 4 is a longitudinal section view illustrating the pulling up of a single crystal silicon ingot I from melted silicon Y in a vitreous silica crucible 20.

### EXAMPLES

Hereinafter, examples of the invention will be described with comparative examples.

### Examples 1 to 4, Comparative Examples 1 to 4

Vitreous silica crucibles were produced according to a rotation mold method, using a vitreous silica crucible provided with arc discharge device having a carbon electrode shown in Table 1, and properties of the obtained crucible were examined. A single crystal silicon was pulled up using the vitreous silica crucible. The result is shown in Table 1.

As shown in Table 1, in all of the vitreous silica crucibles produced using the high-purity carbon electrode (Example 1 to 4) according to the invention, it is possible to obtain a single crystal yield of 70% or more, and particularly, in a vitreous silica crucible produced using a carbon electrode in which the difference in density of the electrode is 0.02 g/cm³ or less and the maximum diameter of carbon particles is 0.05 mm or less, no black foreign material and no concave portion are created on the inner surface of the crucible, and a single crystal yield is as high as 84%.

In vitreous silica crucibles (Comparative Examples 1 and 2) having an excessively large maximum diameter of carbon particles in which the electrode density is substantially the same as that of the invention, many black foreign materials and concave portions occur, and thus the single crystal yield is very low. In a vitreous silica crucible (Comparative Example 3) having an excessively high electrode density and a vitreous silica crucible (Comparative Example 4) having an excessively low electrode density, many black foreign materials and concave portions are created similarly with Comparative Examples 1 and 2, and thus a single crystal yield is very low.

TABLE 1

| | | | | Property of | | | |
|---|---|---|---|---|---|---|---|
| | | | | Vitreous silica | | | |
| | Electrode | | | Crucible | | | |
| | | Difference | Maximum | Black | | | |
| | Density | in Density | Diameter | Foreign | Concave | Single crystal | |
| | [g/cm³] | [g/cm³] | [μm] | Material | Portion | Yield | Assessment |
| Ex. 1 | 1.65~1.67 | 0.03 | 0.01 | 0.0 | 0.0 | 84% | ⊚ |
| Ex. 2 | 1.65~1.67 | 0.02 | 0.02 | 0.0 | 0.0 | 84% | ⊚ |
| Ex. 3 | 1.65~1.67 | 0.02 | 0.05 | 0.0 | 0.0 | 84% | ⊚ |
| Ex. 4 | 1.65~1.67 | 0.03 | 0.05 | 0.6 | 4.8 | 77% | ◯ |
| Comp. 1 | 1.65~1.67 | 0.03 | 0.10 | 10.6 | 100< | 30% | X |
| Comp. 2 | 1.65~1.67 | 0.02 | 0.30 | 21.4 | 100< | 25% | X |
| Comp. 3 | 1.87~1.90 | 0.03 | 0.05 | 12.4 | 100< | 20% | X |
| Comp. 4 | 1.54~1.56 | 0.02 | 0.80 | 17.0 | 100< | 20% | X |

(Note)
A numerical value of black foreign materials and concave portions denotes the number of those on an inner surface of a crucible.
A maximum diameter denotes a maximum particle diameter of carbon particles forming an electrode.
Assessment:
⊚ denotes very good,
◯ denotes good,
X denotes poor

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. An arc melting high-purity carbon electrode used to heat and melt silica powder by arc discharge, wherein the density of the carbon electrode is equal to or more than 1.60 g/cm³ and equal to or less than 1.80 g/cm³, and the carbon electrode is formed of high-purity carbon particles having diameters of 0.05 mm or less.

2. An apparatus for producing a vitreous silica crucible comprising:
an arc discharge device having the carbon electrode according to claim 1; and
a bottomed cylindrical mold, the inside of which is heated by the arc discharge device.

3. A vitreous silica crucible for pulling-up a single crystal silicon, produced or reproduced using the producing apparatus according to claim 2.

4. A method for pulling up a single crystal silicon using the vitreous silica crucible according to claim 3, the method comprising the steps of:
melting polycrystal silicon in the crucible; and
immersing a seed of single crystal silicon in the melted silicon and pulling up a single crystal silicon ingot.
